(19) United States
(12) Patent Application Publication
(10) Pub. No.: US 2008/0315238 A1
(43) Pub. Date: Dec. 25, 2008

(54) Porous Circuitry Material for Led Submounts

(76) Inventors: Lucas Johannes Anna Maria Beckers, Eindhoven (NL); Koen Van Os, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 12/097,355

(22) PCT Filed: Nov. 28, 2006
(86) PCT No.: PCT/IB2006/054471

§ 371 Date: Jun. 13, 2008

(30) Foreign Application Priority Data
Dec. 22, 2005 (EP) 05112772.8

(51) Int. Cl. H01L 33/00; H01L 21/00

(52) U.S. Cl. 257/99; 438/26; 257/E33.001; 257/E21.001

(57) ABSTRACT

A submount comprising a ceramic substrate and a circuitry arranged thereon is provided. The circuitry comprises an electrically conducting porous material comprising at least one noble metal doped with at least one non-noble metal, the surface of at least portions of said electrically conducting porous material comprises oxides of said non-noble metals, and said ceramic substrate is bonded to said porous electrically conducting material via said oxides of said non-noble metals.

The present invention relates to a submount, comprising a ceramic substrate and a circuitry arranged thereon, as well as a light-emitting device comprising at least one light emitting diode and a submount of the present invention. The present invention further relates to a method for the manufacture of such a submount and of such a light-emitting device of the present invention.

Semiconductor based light-emitting devices, such as light-emitting diode (LEDs) and laser diode (LDs) based light emitting devices, are among the most efficient and robust light sources currently available.

In a LED-based light-emitting device, a light emitting diode is typically arranged on a substrate and is connected to a circuitry arranged on the substrate.

In high power applications, where single solid-state light emitting devices with an effect of up to 3 Watts per square mm or arrays of such devices, with a total effect of up to 100 Watts or more, a lot of heat is dissipated from the light emitting devices. Temperatures of up to 250° C. are easily reached for such high power application.

Such high power applications call for special materials being used in the devices. On one hand, both the circuitry material and the substrate material must stand the high temperatures. On another hand, both the circuitry material and the substrate material have to be able to handle the high currents in such devices. For the circuitry, this requires a material having a high conductivity and for the substrate, this requires a material having a good insulating capacity.

In the meantime, the increasing competition in the field requires the devices to be easy to manufacture in high volume and to a low cost.

One example of light emitting devices of this type is described in US patent application US 2004/0169466, to Suchiro et al, showing a light-emitting diode based device having an AlN substrate on which a circuitry is formed by Ag-plating.

However, the Ag plated circuitry described in US 2004/0169466 has a thermal coefficient of expansion that is much higher than the thermal coefficient of expansion for the AlN substrate. Thus, high temperature changes in the device gives temperature induces stress forces in the device, leading to a high probability for disconnection of the plated circuitry or the peeling of the plated circuitry from the substrate.

In US 2004/0169466, this problem is addressed by arranging a radiation plate on the backside of the AlN substrate to conduct the heat away from the substrate into the surrounding air. This solution reduces the probability for the deleterious temperature changes to take place. However, it does not take away the fact problem of disconnection and peeling of the plated circuitry in case the deleterious temperature changes take place.

It is an object of the present invention to overcome this problem, and to provide a submount, especially a submount for arranging light emitting diodes and/or other heat dissipating components thereon, comprising a circuitry arranged on a substrate, which submount is resistant to high temperatures and temperature changes.

Another object of the present invention is to provide devices, especially light emitting devices or other heat dissipating devices, comprising light emitting diodes and/or other heat dissipating components arranged on such a submount which is resistant to high temperatures and temperature changes.

Yet another object of the present invention is to provide a method for the manufacture of a submount and/or a device as mentioned above, which is resistant to high temperatures and temperature changes.

Yet another object of the present invention is to provide components which may be used in the manufacture of such submounts and/or devices as mentioned above The inventors have found that a liquid composition comprising particles of at least one noble metal doped with at least one non-noble metal dispersed in a liquid medium may be used to at least partly meet the above objects. The present inventors have found that when such a liquid composition is arranged on a substrate and heated sufficiently, the particles fuses while the liquid medium evaporates, giving a porous structure, while the non-noble metals oxidizes, thus forming a porous electrically conductive material on the surface of the substrate, and that this material exhibits a strong binding to the substrate due to the oxidation.

Thus, in a first aspect the present invention relates to a submount comprising a ceramic substrate and a circuitry arranged thereon, wherein said circuitry comprises an electrically conducting porous material comprising at least one noble metal doped with at least one non-noble metal. The surface of at least portions of said electrically conducting porous material comprises oxides of said non-noble metals, and said ceramic substrate is bonded to said porous electrically conducting material via said oxides of said non-noble metals.

Typically, the porosity of said porous composition is in the range of from 25 to 75%.

Such a submount has several advantages over conventional submounts. For example, the porous structure of the circuitry makes the circuitry more ductile, and will thus not easily break if the substrate on which it is mounted expands or contracts, for example due to changes in temperature.

Further, the oxides of the non-noble metals exhibits strong binding to the ceramic substrates, which prevents peeling of the circuitry from the substrate.

In submounts of the present invention, the portions of said electrically conducting porous material where the surfaces comprises oxides of said non-noble metals may be enriched in said non-noble metals. Thus, the oxidized portions of the circuitry contains more of the non-noble metals, than the non-oxidized portions of the circuitry. During the oxidation of the non-noble metals, they may under certain circumstances migrate towards the surface of the forming porous material, forming aggregates having a higher concentration of the (oxidized) non-noble metals. This results in a series of discrete locations for bonds between the substrate and the circuitry, which yields a ductile circuitry.

In embodiments of the present invention, said at least one noble metal may be selected from the group consisting of silver, gold, palladium, platinum, rhenium and combinations thereof.

Noble metals from this group exhibit a high electrical capacity and are thus suitable as the main conducting elements of the circuitry material.

In embodiments of the present invention, said at least one non-noble metal may be selected from lead, vanadium, tellurium, bismuth, arsenic, antimony, tin, chrome and combinations thereof.

Non-noble metals from this group are easily oxidized, and the oxides of these non-noble metals exhibit strong binding to ceramic substrates

In preferred embodiments, the noble metal is silver and the non-noble metals are lead and vanadium. Upon oxidization, lead and vanadium together form a lead vanadate glass which provides a strong bond to the substrate.

In embodiments of the present invention, the ceramic substrate may comprise a material selected the group consisting of aluminum nitride and silicon carbide.

In general non-oxide substrates, such as, but not limited to, the above-mentioned, are preferred over oxide-substrates, such as alumina or silica substrates, due to that non-oxide substrates forms stronger bonds to the oxidized non-noble metal(s) of the circuitry.

In embodiments of the present invention, the thermal expansion coefficient of the electrically conducting porous material forming the circuitry may be matched to the thermal expansion coefficient of said ceramic substrate.

It is advantageous that the thermal expansion coefficients of the substrate material and circuitry material are matched, as this further relieves the temperature change induced stresses on the bond between the circuitry and the substrate.

It is further advantageous that the thermal expansion coefficients of the circuitry material and of any heat dissipating electrical component attached to the circuitry are matched, as this further relieves the temperature change induced stresses on the bond between the circuitry and such electrical components.

In a second aspect, the present invention provides a light-emitting device, comprising a submount of the present invention, and at least one light emitting diode being arranged on the submount and electrically connected to the circuitry. In a third aspect, the present invention provides a method for the manufacture of a submount for a light emitting diode.

Such a method may comprise providing a ceramic substrate; arranging on said ceramic substrate a circuitry pattern of a composition comprising particles of at least one noble metal doped with at least one non-noble metal, said particles being dispersed in a liquid medium; and heating said composition at a temperature at which at least part of the liquid medium is evaporated and at least part of said non-noble metals are oxidized.

In the liquid composition, part of the noble metal at the surface of the particles is oxidized. However, upon heating, the oxidized noble metal(s) looses its oxygen atoms. On the other hand, the non-noble metal(s) doped into the noble metal becomes even more oxidized during this heating and provides opportunity for binding to the ceramic substrate via the oxygen atoms of the oxides.

The particles of the composition are fused together during this heating step, and due to the evaporation of the liquid medium (typically an oil), the remaining structure after this heating is a porous electrically conducting material, which is bound to the substrate surface. In embodiments of the present invention, said at least one noble metal may be selected from the group consisting of silver, gold, palladium, platinum, rhenium and combinations thereof.

Noble metals from this group exhibit a high electrical capacity and are thus suitable as the main conducting elements of the circuitry material. Further, oxides of these noble materials loose their oxygen at temperatures where the non-noble metals easily are oxidized.

In embodiments of the present invention, said at least one non-noble metal may be selected from lead, vanadium, tellurium, bismuth, arsenic, antimony, tin, chrome and combinations thereof.

Non-noble metals from this group are easily oxidized at temperatures where oxidized noble materials looses their oxygen atoms, and the oxides of these non-noble metals exhibits strong binding to ceramic substrates

In embodiments of the present invention, the heating is performed in a temperature range from about 250° C. to about 500° C., typically between 300 and 450° C.

Typically the heating is performed for a time of from 3 to 25 minutes, such as from 5 to 20 minutes, for example from 10 to 15 minutes.

In a fourth aspect, the present invention provides a method for the manufacture of a light emitting device, which method may comprise: a method according to the present invention for the manufacture of a submount; arranging at least one light emitting diode on the substrate; and electrically connecting said at least one light emitting diode to the circuitry.

In embodiments of the present invention, at least one light emitting diode may be arranged on the ceramic substrate during the heating, such that the at least one light emitting diode is electrically connected to the circuitry and bonded to the submount by means of this heating.

In a fifth aspect, the present invention provides the use of a composition comprising particles of at least one noble metal doped with at least one non-noble metal, said particles being dispersed in a liquid medium, for the manufacture of a submount or other devices of the present invention.

These and other aspects of the present invention will now be described in more detail, with reference to the appended drawings showing a currently preferred embodiment of the invention. The drawings are not to scale and for the sake of legibility, some dimensions or the size of some components may be exaggerated.

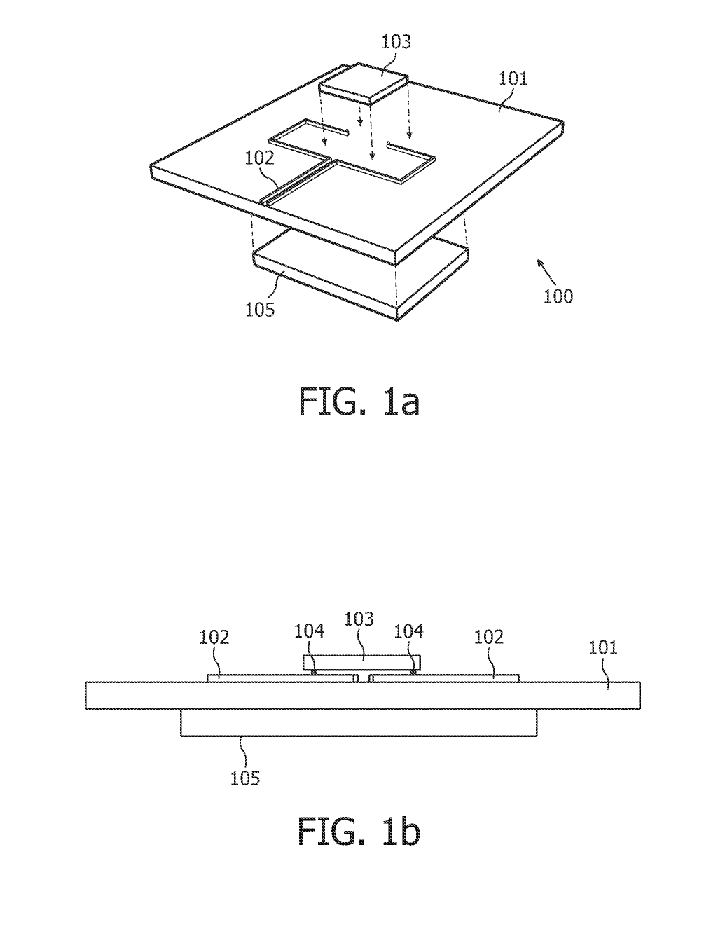

FIG. 1a illustrates in perspective view a light emitting device of the present invention comprising a submount of the present invention and a light emitting diode arranged thereon. FIG. 1b is a cross sectional view along the line I-I in FIG. 1a.

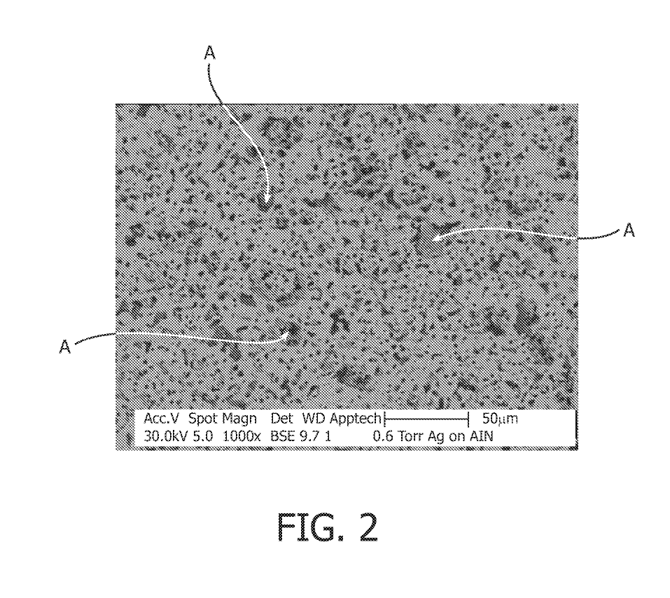

FIG. 2 is a SEM-photo (scanning electron microscopy) of a circuitry material obtained according to the present invention, showing the porous structure of the material, where arrow A indicates a portion of the material being enriched in (oxidized) non-noble metals, i.e. such a portion of the material where the content of non-noble metals is higher.

A light-emitting device 100 of the present invention is illustrated in the FIGS. 1a and 1b. The device comprises a submount of the present invention comprising a substrate 101 and a circuitry 102 arranged thereon. On an area suitable therefore, a light emitting diode (LED) 103 is physically bonded to the substrate 101 and electrically connected to the circuitry 102 via electrically conducting solder bumps 104.

Optionally, a heat sink 105 may be arranged in the bottom side of the substrate 101, for example at a location corresponding to the location of the LED 103, in order to conduct heat away from the device.

The substrate 101 may be of any ceramic material known to those skilled in the art as suitable for use as substrates for light emitting diodes or other heat dissipating electrical components. Examples of suitable ceramic substrates include alumina, quartz, calcium zirconate, frostbite, SiC, graphite, fused silica, mulite, cordierite, zirconia, beryllia and aluminum nitride (AlN). Preferably, the substrate is of made of AlN or SiC. Ceramic substrates are preferred due to good electrical isolating properties and high heat conductive properties. Thus, high driving currents can be allowed for electrical components arranged on the submount. Meanwhile, the heat dissipated by such electrical components is effectively conducted away from the device.

Non-oxide substrates are preferred as they provide a strong bond to the circuitry, as will be discussed below.

AlN is a preferred substrate material as it has good electrical isolating properties combined with high heat conductive properties and relatively low thermal expansion coefficient.

The circuitry 103 comprises an electrically conducting porous material comprising at least one noble metal doped with at least one non-noble metal. The surface of at least portions of said electrically conducting porous material comprises oxides of said non-noble metals. Typically, the ceramic substrate 101 is bonded to the porous electrically conducting material via said oxides of said non-noble metals.

Examples of metals for use in the present invention includes metals which do not oxidize at temperatures of up to at least 300° C. in the presence of air and/or water. Examples of such metals include noble metals, such as Ag, Au, Pt, Pd and Re as well as combinations of these.

Silver (Ag) is a preferred metal due to the high electrical conductivity and the high thermal conductivity. Thus, high driving currents can be allowed for electrical components connected to the circuitry. Meanwhile, the heat dissipated by such electrical components is effectively conducted away from the device.

The circuitry material also comprises portions where the surface comprises oxidized non-noble metals, such as oxides of lead, vanadium, tellurium, bismuth, arsenic, antimony, tin, chrome and combinations thereof. Typically, these oxides form a glassy phase on the surface of the material.

One preferred combination of non-noble metals are lead and vanadium, which in oxidized state forms a lead-vanadate glass phase on portions of the circuitry surface.

The circuitry material is of a porous structure. The porosity of the circuitry material is typically in the range of from about 25 to about 75%, such as in the range of from about 40 to 60%.

Circuitry materials of higher and lower porosities may also be used.

Advantageously, the porosity and the compositional ratio of the circuitry material are chosen such that the thermal expansion coefficient of the circuitry material matches the thermal expansion coefficient of the substrate material.

The porous structure of the circuitry material is advantageous here as it makes the circuitry more ductile that if would have been in a non-porous form.

As used herein, the term “matched thermal expansion coefficient” relates to the difference between the thermal expansion coefficient (CTE) of the circuitry and the thermal expansion coefficient of the substrate material. In order to be matched, the difference should be so small that temperature change induced stresses, due to the difference in thermal expansion coefficients between the two materials, does not cause disconnection of the circuitry or peeling of the circuitry from the substrate.

Furthermore, the thermal expansion coefficient of the circuitry material should preferably also be matched to the thermal expansion coefficient of any heat dissipating electrical component, such as a light emitting diode, being arranged on the submount and connected to the circuitry. If the thermal expansion coefficient of the substrate material is different from that of the heat dissipating electrical component (light emitting diode), the thermal expansion coefficient of the circuitry material should be in between that of the substrate material and the heat dissipating electrical component.

Typically, as will be described more in detail below in the description of a preferred manufacturing method, the circuitry is applied on the substrate surface as a liquid composition comprising particles of the noble metals doped with the non-noble metals in a liquid medium, typically an oil. The liquid composition, arranged on the substrate, is then heated to a temperature at which the non-noble metals oxidize and the oil evaporates from the liquid composition. What is left after cooling is a porous and solid/amorphous circuitry material, which has the desired properties regarding thermal expansion coefficient, thermal conductivity and electrical conductivity.

In addition, the oxidized non-noble metals binds strongly to the substrate material during this heating process, and thus, the resulting circuitry is mechanically secured on the substrate surface. The oxides of the non-noble metals binds strongly to the substrate material, especially where the substrate material is of a non-oxide ceramic material, where the surface easily can bind oxygen.

In addition to the strong mechanical bonding obtained, the binding between the non-noble metals and material in contact with the circuitry during the oxidation process also provides for a good bonding to materials which can be used as encapsulants for coupling the light out of LEDs, such as glass or ceramic encapsulants.

The circuitry material may also be suitable for binding and optically connecting additional components to the submount. For example in some cases, it may be desirable to attach an optical component, such as a refracting element, such as a lens, or a scattering component, on top of an LED arranged on the submount. Especially in cases where such components are made of ceramics or glass materials, the circuitry material may provide a good optical coupling between the submount and such optical components, as well as a mechanically strong attachment.

Furthermore, the noble metals of the circuitry material is typically reflective, and by arranging such material near on the surface of the substrate near an LED, the light emitted by the LED may be reflected in the circuitry material, such as to increase the light utilization of the device.

Any type of light emitting diode (LED) 103, including inorganic based LEDs, organic based LEDs (OLEDs) and polymer based LEDs (polyLEDs) may be used in a light emitting device of the present invention. Further, a light-emitting device of the present invention may comprise more than one LED on each submount.

Especially, as will be realized by those skilled in the art, inorganic LEDs, which at least for a short time period can withstand the high temperatures (˜250-500° C.) used for producing the circuitry, are preferred.

In FIG. 1, a flip-chip type LED is illustrated, having both the anode and the cathode connector arranged on the lower side of the LED. However, also other types of LEDs, such as top-to-bottom type LED, having the anode and cathode connector arrange on opposite sides of the LED may be used. The circuitry material is well suited for the attachment of wire bonds, such as for example wire bonds from the topside of top-to-bottom LEDs

A submount of the present invention is especially advantageously used with high-power LEDs, such as LED having an effect of up to 3 Watts/mm² or even more, as such LEDs dissipate a lot of heat in operation, and the submount of the present invention is specially designed to handle high currents and high temperature changes.

As is illustrated in FIG. 1, the LED is connected to the circuitry via solder bumps 104. Such solder bumps may be of any suitable material known to those skilled in the art, including but not limited to, indium, gold, AuSn, PbSn, SnAgCu, BiSn, PbAg and AgCu.

However, in some embodiments of the present invention, the solder bumps 104 may be omitted or alternatively made of the circuitry material. For example, when using high temperature resistant LEDs (or other electrical components to be connected to the circuitry), they may be placed in contact with the liquid circuitry composition before the heating step, such that they are present during the oxidation process. This gives a strong mechanical bond between the LED and the circuitry, and as discussed above, a good optical coupling between the LED and the circuitry (and the substrate, via the oxidized circuitry material).

The submount as described above (i.e. the substrate and the circuitry arranged thereon) forms a preferred aspect of the present invention.

The light-emitting device as described above, comprising a submount of the present invention and an LED connected thereto, forms another preferred aspect of the present invention.

The liquid composition utilized to form the circuitry comprises particles of at least one noble metal doped with at least one non-noble metal, said particles being dispersed in a liquid medium. The noble metals and the non-noble metals are selected as previously disclosed.

Typically, the liquid medium is an oil. The liquid medium should advantageously be possible to evaporate at a temperature in the range of from 250 to 500° C., typically from 300 to 450° C.

The metals are preferably present in the liquid composition in the form of particles with dimensions in the range of from about 1-100 μm, for example granule particles having a size in the range of from about 1 to about 10 μm, such as from about 1 to about 5 μm. Alternatively, the metals are in the form of flakes having a thickness of from about 1 to about 10 μm, such as from about 1 to about 5 μm, typically around 2 μm, and a diameter of from about 10 to about 100 μm, such as from about 10 to about 50 μm, typically around 30 μm.

The viscosity of the liquid composition in a form suitable for use depends on the intended method of application and may vary from the order of 1 mPas for ink jet printing applications to 10-100 Pas for stencil printing applications.

One example of such a liquid composition, which has been successfully used in practice, comprises particles of silver as the noble metal, doped with lead and vanadium as the non-noble metals.

The use of liquid composition as described above in the manufacture of a submount of the present invention is forms a preferred aspect of the invention.

A submount of the present invention is typically manufactured by a method comprising: (i) providing a ceramic substrate material; (ii) arranging a circuitry pattern on the substrate material of a liquid composition comprising particles the noble metal(s) doped with non-noble metal(s); and (iii) heating the liquid composition at a temperature at which at least part of the liquid medium evaporates and the non-noble metals oxidizes, for example to form a glassy phase, resulting in a self supporting porous, electrically conductive solid/amorphous compound.

In this method, the substrate and the liquid composition are as described above.

The temperature for forming the glassy phase and evaporating the liquid medium may be in the range of from about 250° C. to about 500° C. Typically, this temperature is about 350° C. The submount is typically incubated at this temperature for a time period of from about 3 to about 20 minutes, for example about 10 minutes, in order to adequately evaporate the liquid medium and oxidizing the non-noble metal(s). Alternatively, longer or shorter times may be required or enough to reach the desired end result.

The liquid composition may be arranged on the substrate by any suitable method including, but not limited to, ink jet printing, pin transfer, dispensing and stencil printing.

A method for the manufacture of a submount forms a preferred aspect of the present invention.

FIG. 2 shows a SEM-image of a porous circuitry material obtained on an AlN substrate by a method of the present invention. The scale-marker in the SEM-image correlates to a distance of 50 μm.

For obtaining this porous structure, the particles of the liquid composition comprised approximately 97.2% (w/w) Ag, 0.6% (w/w) V and 2.2% (w/w) Pb, corresponding to approximately 97.5 molar % Ag, 1.25 molar % V and 1.25 molar % Pb.

The particles constituted approximately 50 vol % of the liquid composition.

The composition was arranged on a AlN substrate and was heated at 350° C. for 15 minutes.

The resulting porous structure seen in FIG. 2 contains several darker portions (indicated by the arrows A), which are portions of the porous material having an surface of lead-vanadate glass (oxidized non-noble metals). This image clearly shows the formation of a plurality of such discrete portions.

The formed structure was subjected to an elemental analysis, and the overall composition was as follows in table 1, where the Al-portion emanates from the AlN-substrate.

TABLE 1
Overall elemental analysis*

| Element | Wt % | Atom % |
|---|---|---|
| Al | 6.18 | 20.9 |
| Ag | 91.11 | 77.11 |
| V | 0.59 | 1.05 |
| Pb | 2.12 | 0.94 |

*the contribution of oxygen and nitrogen is not detected in this elemental analysis.

As is apparent from these results, the elemental proportions between Ag, V and Pb are near their initial values.

A portion indicated by an arrow A in the SEM-image was separate subjected to an elemental analysis, and the composition of this darker portion was as follows in table 1, where the Al-portion emanates from the AlN-substrate.

TABLE 2
Elemental analysis of oxidized portion*

| Element | Wt % | Atom % |
|---|---|---|
| Al | 8.57 | 28.35 |
| Ag | 71.17 | 58.89 |
| V | 3.04 | 5.34 |
| Pb | 17.22 | 7.42 |

*the contribution of oxygen and nitrogen is not detected in this elemental analysis.

These results clearly indicate an enrichment of the non-noble metals V and Pb in the darker regions of the porous material.

A light-emitting device of the present invention may be manufactured by a method based on the above method for manufacturing a submount.

In one embodiment, the submount is manufactured as described above, and an LED, or a plurality of LEDs, is connected to the circuitry by means of solder bumps by conventional methods known to those skilled in the art.

In another embodiment, the light-emitting device is manufactured by arranging an LED (or LEDs) on the substrate between step (ii) and step (iii) in the submount manufacturing method above, such that the LED is present during the heating step and therefore connected electrically and optionally optically to the circuitry during the glass formation process. This yields a strong LED-circuitry connection. In addition, the conventionally used solder bumps, as well as the separate soldering step may be omitted.

The person skilled in the art realizes that the present invention by no means is limited to the preferred embodiments described above. On the contrary, many modifications and variations are possible within the scope of the appended claims. For example, a submount of the present invention is not limited to the use in conjunction with light emitting diodes. As will be realized by those skilled in the art, such a submount may also be used in conjunction with any electrical component, and is especially advantageous for use with heat dissipating electrical components, typically semiconductor components, such as non-light emitting diodes, transistors, etc. A device of the present invention may also comprise additional components. In addition, a device of the present invention is typically connected or connectable to a driving unit, which provides the electrical current driving the electrical components.

To summarize, the present invention relates to a submount comprising a ceramic substrate and a circuitry arranged thereon, where said circuitry comprises an electrically conducting porous material comprising at least one noble metal doped with at least one non-noble metal, the surface of at least portions of said electrically conducting porous material comprises oxides of said non-noble metals, and said ceramic substrate is bonded to said porous electrically conducting material via said oxides of said non-noble metals.

1. A submount comprising a ceramic substrate (101) and a circuitry (102) arranged thereon, characterized in that
said circuitry (102) comprises an electrically conducting porous material comprising at least one noble metal doped with at least one non-noble metal,
the surface of at least portions of said electrically conducting porous material comprises oxides of said non-noble metals, and
said ceramic substrate is bonded to said porous electrically conducting material via said oxides of said non-noble metals.

2. A submount according to claim 1, wherein said portions of said electrically conducting porous material where the surfaces comprises oxides of said non-noble metals are enriched in said non-noble metals.

3. A submount according to claim 1, wherein the porosity of said porous composition is in the range of from 25 to 75%.

4. A submount according to claim 1, wherein said noble metals are selected from the group consisting of silver, gold, palladium, platinum, rhenium and combinations thereof.

5. A submount according to claim 1, wherein said non-noble metals are selected from lead, vanadium, tellurium, bismuth, arsenic, antimony, tin, chrome and combinations thereof.

6. A submount according to claim 1, wherein said at least one noble metal is silver and said at least one non-noble metal is lead and vanadium.

7. A submount according to claim 1, wherein said ceramic substrate (101) comprises a material selected the group consisting of aluminum nitride and silicon carbide.

8. A submount according to claim 1, wherein said thermal expansion coefficient of said electrically conducting porous material is matched to the thermal expansion coefficient of said ceramic substrate.

9. A light emitting device (100), comprising a submount according to claim 1, and at least one light emitting diode (103) being arranged on said submount and electrically connected to said circuitry (102).

10. A method for the manufacture of a submount, comprising:
providing a ceramic substrate;
arranging on said ceramic substrate a circuitry pattern of a composition comprising particles of at least one noble metal doped with at least one non-noble metal, said particles being dispersed in a liquid medium; and
heating said composition at a temperature at which at least part of the liquid medium is evaporated and at least part of said non-noble metals are oxidized.

11. A method according to claim 10, wherein said noble metals are selected from the group consisting of silver, gold, palladium, platinum, rhenium and combinations thereof.

12. A method according to claim 10, wherein said non-noble metals are selected from lead, vanadium, tellurium, bismuth, arsenic, antimony, tin, chrome and combinations thereof.

13. A method according to claim 10, wherein said at least one noble metal is silver and said at least one non-noble metal is lead and vanadium.

14. A method according to claim 10, wherein said ceramic substrate (101) comprises a material selected the group consisting of aluminum nitride and silicon carbide.

15. A method according to claim 10, wherein said heating is performed at a temperature in the range of from about 250° C. to about 500° C.

16. A method according to claim 10, wherein said heating is performed for a time of from 3 to 25 minutes.

17. A method according to claim 10, wherein said composition is arranged on said ceramic substrate by printing.

18. A method for the manufacture of a light emitting device, comprising a method according to claim 10, and further comprising:
arranging at least one light emitting diode on said substrate; and
electrically connecting said at least one light emitting diode to said circuitry.

19. A method for the manufacture of a light emitting device according to claim 18, wherein at least one light emitting diode is arranged on said ceramic substrate during said heating, such that said at least one light emitting diode is connected and bonded to said circuitry.

20. The use of a composition comprising particles of at least one noble metal doped with at least one non-noble metal, said particles being dispersed in a liquid medium, for the manufacture of a submount.

21. A submount obtainable by the method according to claim 10.

22. A light-emitting device obtainable by the method according to claim 18.
